(19) United States
(12) Patent Application Publication
(10) Pub. No.: US 2008/0211769 A1
(43) Pub. Date: Sep. 4, 2008

(54) Input Device For Content Providing Device and Method of Operating the Same

(75) Inventors: Jin-Woo Chung, Gyeonggi-do (KR); Bang-Won Lee, Gyeonggi-do (KR); Young-Ho SHIN, Yongin-si (KR); Chul-Yong Joung, Seoul (KR)

Correspondence Address: CANTOR COLBURN, LLP, 20 Church Street, 22nd Floor, Hartford, CT, 06103, US

(73) Assignee: ATLAB INC., Yongin-si (KR)

(21) Appl. No.: 11/994,679

(22) PCT Filed: Jun. 30, 2006
(86) PCT No.: PCT/KR2006/002572

§ 371 Date: Jan. 4, 2008

(30) Foreign Application Priority Data
Jul. 4, 2005 (KR) 10-2005-0059895
Feb. 13, 2006 (KR) 10-2006-0013896

(51) Int. Cl. G06F 3/01; H03M 11/00

(52) U.S. Cl. 345/157; 341/34

(57) ABSTRACT

An input device for a content providing device and a method of operating the same are provided. The input device includes: a pressure sensor having first pressure pads varying impedance according to contact strength, and periodically generating and outputting first pressure data having values corresponding to impedance of each of the first pressure pads; a button information generator for generating and outputting button information corresponding to the first pressure pad having the largest pressure data, when receiving the first pressure data; a pointing information generator for obtaining a position value of the first pressure pad having the largest pressure data when receiving the first pressure data, comparing the position value with the previously obtained position value to calculate a movement value of a contact position, and generating and outputting pointing information having the calculated movement value; and an operation selection unit for transmitting the first pressure data to the button information generator when the first pressure data transmitted from the pressure sensor is different from the previously obtained data and has a value larger than a button input value, and transmitting the first pressure data to the pointing information generator when the first pressure data transmitted from the pressure sensor is different from the previously obtained data and has value smaller than a pointing input value. Therefore, it is possible to perform various kinds of input operations using a single input device

### TECHNICAL FIELD

The present invention relates to a content providing device, and more particularly, to an input device for a content providing device and a method of operating the same that are capable of detecting various kinds of input operations using a plurality of input sensors or a plurality of contact sensors.

### BACKGROUND ART

A content providing device may be referred to as a portable device such as a mobile phone, an MP3 player, a PMP player, an electronic dictionary, or the like, capable of storing content information and outputting the content information through a display device or an audio device in response to a user's request.

While a conventional content providing device can store small content information and display the stored content information in a simple display manner only, a state-of-the-art content providing device can store and display content information with the same level as a desktop computer.

Therefore, the content providing device may include various kinds of input devices such as a keyboard and a mouse, similar to the desktop computer. However, since the content providing device should have good mobility features, it is difficult to install a large number or size of input devices in the content providing device.

Referring to FIG. 1, Korean Patent Application No. 2005-114414 discloses a pressure sensor including a pressure pad 161, an input signal generator 140, a reference signal generator 150, a pressure signal generator 160, and a pressure data generator 170 to detect contact strength (or pressure strength) with respect to a pressure pad.

In addition, referring to FIG. 2, Korean Patent Application No. 2005-23382 discloses a contact sensor including a reference signal generator 10, a first signal generator 21, a second signal generator 22, a contact signal generator 30, and a filter 40 to detect a contact of a contact pad.

### DISCLOSURE OF INVENTION

### Technical Problem

In order to solve the problem, the present invention provides an input device for a content providing device capable of performing various input operations and maintaining the size of the input device using a plurality of input sensors and contact sensors, thereby remarkably reducing the number of input buttons, which should be included in the content providing device.

The present invention also provides a method of operating an input device for a content providing device capable of performing various input operations and maintaining the kind and size of the input device using a plurality of input sensors and contact sensors.

### Technical Solution

In accordance with a first exemplary embodiment of the present invention, there is provided an input device for a content providing device including: a pressure sensor having first pressure pads varying impedance according to contact strength, and periodically generating and outputting first pressure data having values corresponding to impedance of each of the first pressure pads; a button information generator for generating and outputting button information corresponding to the first pressure pad having the largest pressure data, when receiving the first pressure data; a pointing information generator for obtaining a position value of the first pressure pad having the largest pressure data when receiving the first pressure data, comparing the position value with the previously obtained position value to calculate a movement value of a contact position, and generating and outputting pointing information having the calculated movement value; and an operation selection unit for transmitting the first pressure data to the button information generator when the first pressure data transmitted from the pressure sensor is different from the previously obtained data and has a value larger than a button input value, and transmitting the first pressure data to the pointing information generator when the first pressure data transmitted from the pressure sensor is different from the previously obtained data and has value smaller than a pointing input value.

In accordance with a second exemplary embodiment of the present invention, there is provided a content providing device including: a user input unit having first pressure pads varying impedance according to contact strength, and generating button information or pointing information according to user's contact strength with respect to the first pressure pads; and a controller for performing, when the button information is received, a data selection operation in response to the button information, determining a content display mode when the pointing information is received, scrolling a screen in response to the pointing information when the display mode is a scroll mode, and moving a cursor displayed on the screen in response to the pointing information when a cursor moving mode.

In accordance with a third exemplary embodiment of the present invention, there is provided a content providing device including: a user input unit having a plurality of key buttons and a plurality of contact sensors, and generating a plurality of button information and a plurality of contact signals; a contact sensor controller for recognizing a contact position or a contact position moving direction in response to the plurality of contact signals, generating scroll information corresponding to the contact position or the contact position moving direction in a scroll mode, and generating cursor moving information corresponding to the contact position in a cursor moving mode; and a main controller for setting a display mode according to a display type of content, scrolling a screen in response to the scroll information generated by the contact sensor controller in the scroll mode, and moving a cursor displayed on the screen in response to the cursor moving information generated by the contact sensor controller in the cursor moving mode.

In accordance with a fourth exemplary embodiment of the present invention, there is provided a method of operating an input device for a content providing device having first and second pressure pads disposed on a keypad and varying impedance according to contact strength of a user, the method including: a pressure data generating step of periodically generating a plurality of first pressure data having values corresponding to impedance of each of the first pressure pads; a determination step of determining whether at least one first pressure data has a value larger than a button input value when a newly obtained first pressure data is different from the previously obtained first pressure data; a button information generating step of obtaining the first pressure pad having the largest first pressure data, and generating and outputting button information corresponding to the obtained first pressure pad, when the at least one first pressure data has a value larger than the button input value as a result of the determination; and a pointing information step of obtaining a position value of the first pressure pad having the largest first pressure data, comparing the position value with the previously obtained position value to calculate a movement value of a contact position, and generating and outputting pointing information having the calculated movement value, when all of the first pressure data have values not more than the pointing input value as a result of the determination.

### ADVANTAGEOUS EFFECTS

As can be seen from the foregoing, an input device in accordance with the present invention can perform various input operations using a plurality of pressure sensors or a plurality of contact sensors, thereby remarkably increasing applicability of the input device. Therefore, a content providing device including the input device in accordance with the present invention can detect more various input operations through a single input device, thereby enabling a user to readily search and select data.

In addition, the input device in accordance with the present invention can replace a plurality of key buttons with a plurality of pressure sensors, or dispose a plurality of contact sensors on the plurality of key buttons or remaining regions except the key buttons, without increasing size of the input device.

### BRIEF DESCRIPTION OF THE DRAWINGS

FIG. 1 is a block diagram of a conventional pressure sensor;

FIG. 2 is a block diagram of a conventional contact sensor;

FIG. 3 is a block diagram of an input device in accordance with an exemplary embodiment of the present invention;

FIG. 4 is a diagram showing position values of respective pressure pads of the input device of FIG. 3;

FIG. 5 and FIG. 6 are a diagram illustrating the operation of a pointing information generator of FIG. 3;

FIG. 7 is a flowchart illustrating a method of operating the input device of FIG. 3;

FIG. 8 is a block diagram of a content providing device having the input device of FIG. 3 in accordance with an exemplary embodiment of the present invention;

FIG. 9 and FIG. 10 are is a diagram illustrating a display mode of the content providing device of FIG. 8;

FIG. 11 to FIG. 15 show external appearances of an input device having the contact sensors of FIG. 2 in accordance with an exemplary embodiment of the present invention;

FIG. 16 shows an external appearance of an input device having the contact sensors of FIG. 2 in accordance with another exemplary embodiment of the present invention;

FIG. 17 is a block diagram of a content providing device having the input device of FIG. 11 to FIG. 15 in accordance with an exemplary embodiment of the present invention;

FIG. 18 is a diagram illustrating the operation of a contact sensor controller of FIG. 11 to FIG. 15; and

FIG. 19 is a flowchart illustrating the operation of the content providing device of FIG. 17.

### BEST MODE FOR CARRYING OUT THE INVENTION

Exemplary embodiments of an input device for a content providing device and a method of operating the same according to the present invention will now be described in detail with reference to the accompanying drawings.

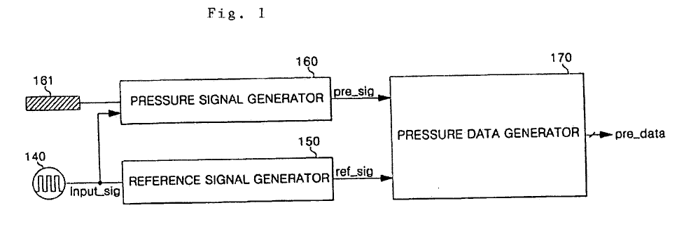

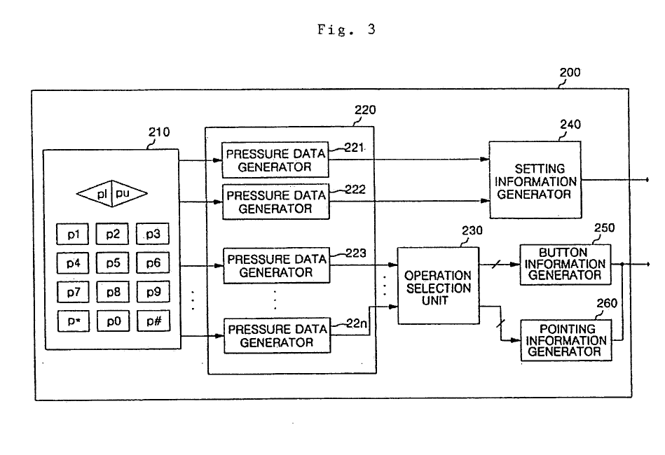

FIG. 3 is a block diagram of an input device in accordance with an exemplary embodiment of the present invention, and the input device of FIG. 3 is implemented using the pressure sensor of FIG. 1.

Referring to FIG. 3, the input device of the present invention includes a keypad 210 having a plurality of pressure pads p0˜p9, p*, p#, pu, and pl, an operation detector 220 having a plurality of pressure data generators 221˜22n corresponding to the plurality of pressure pads p0˜p9, p*, p#, pu, and pl, an operation selection unit 230, a setting information generator 240, a button information generator 250, and a pointing information generator 260.

The keypad 210 includes the plurality of pressure pads p0˜p9, p*, and p#, (hereinafter, referred to as common pads) for simultaneously performing a button function and a pointing function, and the plurality of pressure pads pu, and pl (hereinafter, referred to as setting pads) for performing a setting function. In this process, each of the plurality of common pads p0˜p9, p*, and p# and the plurality of setting pads pu, and pl varies impedance according to contact strength of a user.

The operation detector 220 includes the plurality of pressure data generators 221˜22n respectively corresponding to the plurality of common pads and setting pads p0˜p9, p*, p#, pu, and pl. In this process, each of the pressure data generators 221˜22n periodically obtains impedance of the corresponding common pad or setting pad p0˜p9, p*, p#, pu, or pl according to a sampling cycle, and generates and outputs a pressure data having a value corresponding to the obtained impedance.

At this time, the pressure pad p0 of the present invention is implemented as the pad 161 in FIG. 1, and the pressure data generator 221 is implemented as the input signal generator 140, the reference signal generator 150, the pressure signal generator 160, and the pressure data generator 170. That is, a pair of the pressure pad p0 and the pressure data generator 221 constitutes a pressure sensor of FIG. 1.

The operation selection unit 230 analyzes the pressure data of the common pads periodically transmitted and selects transmission path of the pressure data. That is, when a newly received pressure data is different from the previously received pressure data and at least one pressure data has a value larger than the button input value, the operation selection unit 230 transmits the newly received pressure data to the button information generator 250. When the newly received pressure data is different from the previously received pressure data and all of the pressure data have values smaller than pointing input value, the operation selection unit 230 transmits the newly received pressure data to the pointing information generator 260. On the other hand, when the newly received pressure data is equal to the previously received pressure data, the operation selection unit 230 determines that a user maintains the previous contact state at it is, and transmits no data to the button information generator 250 and the pointing information generator 260.

At this time, the button input value and the pointing input value are reference values for determining whether the common pad is to be used as a button or a pointing device, which can be set depending on a user;s need, under the condition that the button input value is larger than the pointing input value.

The setting information generator 240 obtains the second pressure pad that generates different second pressure data when pressure data of setting pad pu or pl having a different value from the previous pressure data is received from the operation detector 220, and generates and outputs setting information corresponding to the obtained second pressure pad and a pressure data value of the obtained second pressure pad.

While the above embodiment describes two setting pads, if necessary, such setting pads may be added in various ways.

The button information generator 250 stores button information respectively corresponding to the plurality of position values of each common pad p0˜p9, p* and p#. When the plurality of pressure data are received from the operation selection unit 230, the button information generator 250 obtains the common pad having the largest pressure data as a contact pad contacted by the user, and generates button information corresponding to the contact pad.

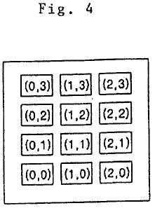

The pointing information generator 260 sets and stores position values of the plurality of common pads p0˜p9, p* and p# on the basis of a mapping relationship shown in FIG. 4. When the plurality of pressure data are continuously received within a moving detection time, the pointing information generator 260 sets the common pad having the largest pressure data as a contact pad contacted by the user to obtain its position value, compares the position value and the previously obtained position value to calculate a movement value of the contact position, and generates pointing information having the calculated movement value.

At this time, the moving detection time is a maximum time that a user should move contact positions of the plurality of pressure sensors in order to perform pointing operation, which can be set according to a user s need.

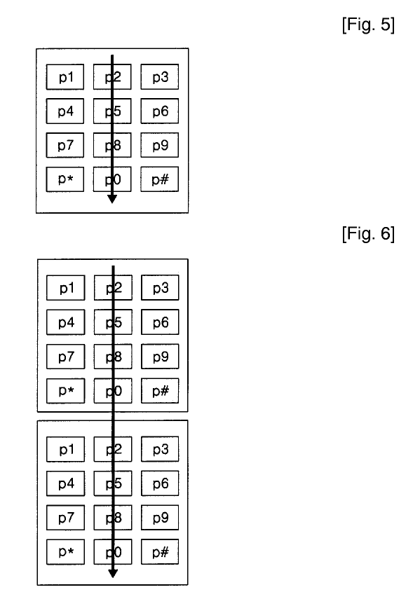

FIG. 5 is a conceptual diagram illustrating a method of generating pointing information of a pointing information generator 260 in accordance with the present invention.

The pointing information generator 260 sets a common pad having the largest pressure data as a contact pad and obtains its position value, when the pressure data of the plurality of common pads p0˜p9, p* and p# are received. When the position values of the contact pads are continuously obtained within the moving detection time, the pointing information generator 260 compares a currently obtained position value with a previously obtained position value to calculate a movement value of the contact position, and generates pointing information having the calculated movement value.

When the currently obtained position value is (x, y) and the previously obtained position value is (x0, y0), the movement value of the contact position is calculated using “formula (x−x0, y−y0)”

For example, when a user continuously contacts the common pads p2, p5, p8 and p0 which are disposed in a line as shown in FIG. 5, the pointing information generator 260 continuously obtains position values (1, 3), (1, 2), (1, 1), and (1, 0) of the contact pads within the movement detection time. Then the pointing information generator 260 generates a movement value (0, −1) when the contact point moves from p2 to p5, from p5 to p8, and from p8 to p0. That is, pointing information having the movement values (0, −1) is continuously generated.

On the other hand, when the pointing information generator 260 does not obtain a new position value until the movement detection time elapses, a pointing operation is terminated, and pointing information is not generated.

For example, when a user continuously contacts the straightly disposed common pads p2, p5 and p8 within the movement detection time, and then maintains the contact with the common pad p8 until the movement detection time elapses, the pointing information generator 260 generates pointing information having the movement value (0, −1) only when the contact point moves from p2 to p5 and from p5 to p8, and generates no pointing information when the contact point maintains p8.

However, when the user continuously contacts the common pads p8 and p0 and obtains a new position value within the movement detection time, the pointing information generator 260 newly generates and outputs pointing information having the movement value (0, −1).

In addition, the pointing information generator 260 previously sets a movement correction value on the basis of a relationship between the common pads p1, p2, p3, p4, p6, p7, p9, p*, p0 and p# disposed on the periphery of the keypad. Therefore, when a user repeatedly contacts the common pads disposed in a line on the periphery of the keypad while maintaining the same directionality, the pointing information generator 260 continuously generates pointing information having the same directionality.

When the input device includes common pads disposed in an n×m matrix, the pointing information generator 260 sets a movement correction value by adding n when an x-axis movement value of a contact position is larger than an x-axis movement limit value, i.e., (n-1), and adding m when a y-axis movement value of a contact position is larger than a y-axis movement limit value, i.e., (m-1).

For example, as shown in FIG. 6, when a user continuously contacts the common pads p2, p5, p8 and p0 having position values (1, 3), (1, 2), (1, 1), and (1, 0) and disposed in a line between upper and lower ends of the keypad, and then continuously contacts the common pads p2, p5, p8 and p0 repeatedly, the contact position of the user is abruptly changed from the lower end to the upper end (from p0 to p2). In this case, the pointing information generator 260 calculates a movement value of this section as (0, −3), and adjusts the movement value using a movement correction value, thereby finally obtaining the movement value (0, −1). Consequently, the pointing information generator 260 continuously generates only the pointing information having the movement value (0, −1).

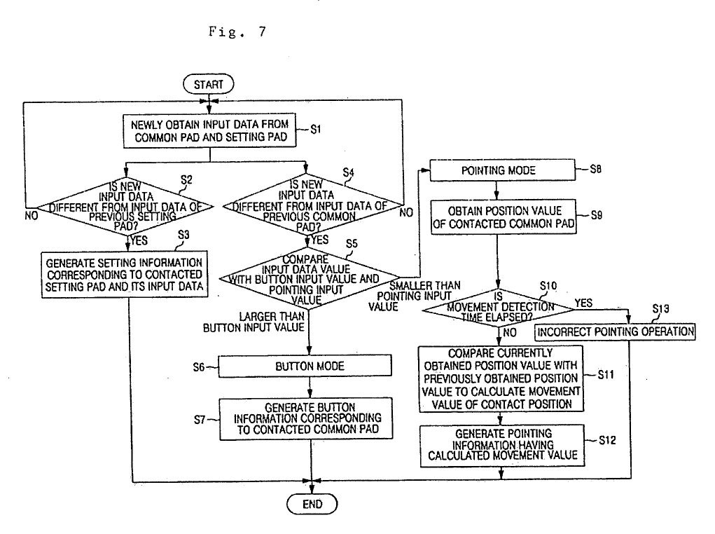

A method of operating an input device in accordance with the present invention will now be described with reference to FIG. 7.

An operation detector 220 newly obtains a plurality of pressure data respectively corresponding to a plurality of common pads and setting pads p0˜p9, p*, p#, pu and pl according to a sampling cycle. Then, the operation detector 220 transmits the pressure data of the plurality of common pads p0˜p9, p* and p# to an operation selection unit 230, and transmits the pressure data of the plurality of setting pads pu and pl to a setting information generator 240 (S1).

The setting information generator 240 determines whether the newly received pressure data of the plurality of setting pads are different from the previously received pressure data of the plurality of setting pads (S2). As a result of the determination of step S2, when the newly received pressure data of the plurality of setting pads are different from the previously received pressure data of the plurality of setting pads, the setting information generator 240 generates the pressure data having values different from the previous pressure value and setting information corresponding to the setting pads having the pressure data, and outputs the pressure data and the setting information to a main body of a content providing device (S3).

At the same time, the operation selection unit 230 also determines whether the newly received pressure data of the plurality of common pads are different from the previously received pressure data of the plurality of common pads (S4).

As a result of the determination of S4, when the newly received pressure data of the plurality of common pads are the same as the previously received pressure data of the plurality of common pads, the operation selection unit 230 determines that a user does not contact any pad or maintains the previous contact, and returns to step S1 to obtain new pressure data.

On the other hand, as a result of the determination of S4, when the newly received pressure data of the plurality of common pads are different from the previously received pressure data of the plurality of common pads, the operation selection unit 230 compares the newly received pressure data of the plurality of common pads with button input values and pointing input values, respectively (S5).

As a result of the comparison of step S5, when at least one pressure data is larger than the button input value, the operation selection unit 230 determines that the user uses the common pads as buttons, sets an operation mode of the input device as a button mode, and then transmits the newly received pressure data to a button information generator 250 (S6). The button information generator 250 obtains a common pad having the largest pressure data as a common pad contacted by a user, and then generates button information corresponding to the obtained common pad (S7).

On the other hand, as a result of the comparison of step S5, when all of the pressure data are smaller than the pointing input value, the operation selection unit 230 sets an operation mode of the input device as a cursor moving mode, and transmits the newly received pressure data to a pointing information generator 260 (S8). The pointing information generator 260 obtains a common pad having the largest pressure data as a common pad contacted by the user, and obtains its position value (S9).

In addition, the pointing information generator 260 determines again whether a new position value is obtained within the movement detection time, in order to determine whether the current pointing operation is a normal pointing operation (S10).

As a result of the determination of step S10, when the new position value is obtained within the movement detection time, the pointing information generator 260 determines that the current pointing operation is normal, compares the new position value with the previous position value through step S9 to calculate a movement value of a contact position (S11), and generates pointing information having the calculated movement value (S12).

On the other hand, as a result of the determination of step S10, when the new position value is not obtained within the movement detection time, the pointing information generator 260 determines that the current pointing operation is abnormal, and does not generate any pointing information (S13).

After generating the setting information, the button information, and the pointing information through the above steps, the input device repeatedly performs steps S1 to S3 to newly obtain pressure data of the plurality of common pads and setting pads p0˜p9, p*, p#, pu and p1, and thus continuously generates setting information, button information, and pointing information.

As described above, the input device in accordance with the present invention includes a plurality of pressure pads to detect various input operations and generate various input information.

While the above input device of the present invention includes the common pads and the setting pads separated from each other, if necessary, a single pressure pad may simultaneously perform functions of a common pad and a setting pad.

For this purpose, the operation selection unit 230 sets a predetermined number of pads p2, p8, p4 and p6, among the plurality of common pads p0˜p9, p* and p#, as combined-use pads. When at least one of the input data of the combined-use pads p2, p8, p4 and p6 is larger than the pointing input value and smaller than the button input value, the operation selection unit 230 transmits the input data of the combined-use pads p2, p8, p4 and p6 to the setting information generator 240. When the input data of the combined-use pads p2, p8, p4 and p6 are received from the operation selection unit 230, the setting information generator 240 obtains the combined-use pads generating a value different from the previous value, and then generates setting information corresponding to the pressure data of the combined-use pad and the obtained combined-use pad and outputs the setting information.

For example, when a user continuously contacts a predetermined number of common pads with a contact strength smaller than the pointing input strength, the pointing information generator 260 continuously generates pointing information. When the user contacts one of the combined-use pads p2, p8, p4 and p6 with a contact strength larger than the pointing input strength and smaller than the button input strength, the setting information generator 240 generates setting information for adjusting scroll speed of a direction corresponding to the contacted pad.

Therefore, the input device of the present invention can generate the pointing information through the plurality of common pads p0˜p9, p* and p#, and simultaneously generate the setting information for adjusting scroll speed of horizontal and vertical directions through the combined-use pads p2, p8, p4 and p6.

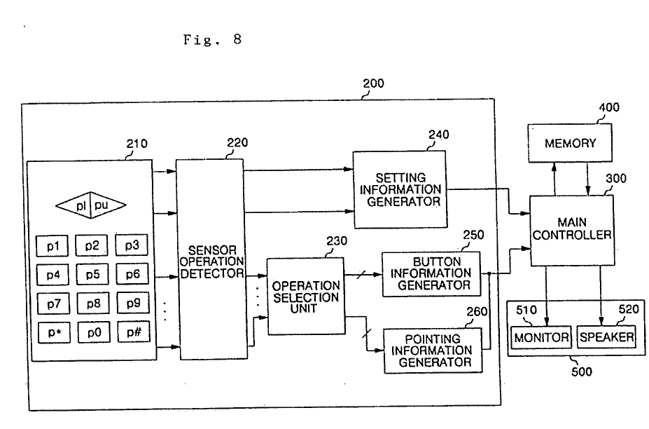

FIG. 8 is a block diagram of a content providing device having the input device of FIG. 3. For the convenience of description, a content providing device implemented as a mobile phone will be described.

Referring to FIG. 8, a mobile phone includes a user input unit 200 implemented as the input device shown in FIG. 3, a main controller 300, a memory 400, and a data output unit 500 having a monitor 510 and a speaker 520.

In the user input unit 200, a plurality of common pads are installed at a conventional mobile terminal, the common pads are disposed in the same array as general buttons (number buttons, a call button, a call-end button, and so on). Setting pads are disposed in the same array as conventional setting buttons (a volume adjustment button, a screen brightness adjustment button, and so on). Therefore, the user input unit 200 generates button information, pointing information, or setting information and outputs it to a main controller 300 depending on the kind and contact manner of the pads contacted by a user.

The main controller 300 detects input operation of the user using the setting information, the button information, or the pointing information transmitted from the user input unit 200, and performs a setting operation, a data selecting operation, or a pointing operation corresponding thereto, thereby performing a basic call operation or a content providing operation. Specifically, the main controller 300 determines a current display mode when pointing information is received during display of content information. When the current display mode is a scroll mode, the main controller 300 performs a scroll operation in response to the pointing information to vertically or horizontally scroll a screen, and when a cursor moving mode, the main controller 300 performs a cursor moving operation in response to the pointing information to move the position of a cursor.

For example, when the main controller 300 receives volume setting information for adjusting volume of the content providing device from the user input device 200, the main controller 300 performs a predetermined setting operation to adjust the volume of the content providing device to a predetermined value. When the main controller 300 receives button information for selecting a number “0” the main controller 300 performs a data selecting operation corresponding to the number “0” to obtain the number “0” as pressure data, and simultaneously display the number “0” on the screen such that the user confirms that the desired number is selected. In addition, when the pointing information is input, the main controller 300 first determines the current display mode, scrolls the screen in a direction corresponding to the pointing information in the case of the scroll mode, and positions the cursor at a specific position corresponding to the pointing information in the case of the cursor moving mode.

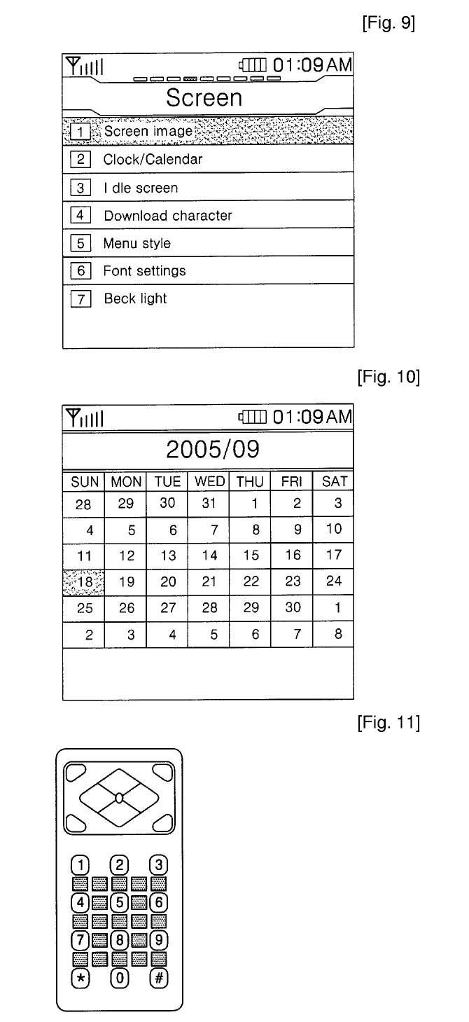

At this time, the scroll mode is a mode that content information to be selected is displayed in a vertical direction as shown in FIG. 9, and the cursor moving mode is a mode that content information to be selected is displayed in vertical and horizontal directions as shown in FIG. 10 and a position of the cursor (i.e., a data selection position) is also movable in vertical and horizontal directions. Of course, the main controller 300 may set the scroll mode and the cursor moving mode using various methods, and thus, content display methods may also be set in various manners.

The memory 400 stores data for providing various programs, menu, and contents required to perform a call operation and a content providing operation of a mobile phone. The monitor 510 of the data output unit 500 converts data transmitted from the main controller 300 under control thereof into user-recognizable characters or figures, and displays them on the screen. The speaker 520 of the data output unit 500 converts the data transmitted from the main controller 300 under control thereof into user-recognizable sound, and outputs the sound.

Therefore, the content providing device shown in FIG. 8 includes the input device 200 for providing button information or pointing information depending on contact strength of a user so that the user can readily search and select content information stored in the content providing device in various manners.

As described above, a content providing device in accordance with an exemplary embodiment of the present invention includes an input device having a plurality of input sensors so that the input device can detect more various input operations to provide various kinds of information, without increasing the kind and size of the input device.

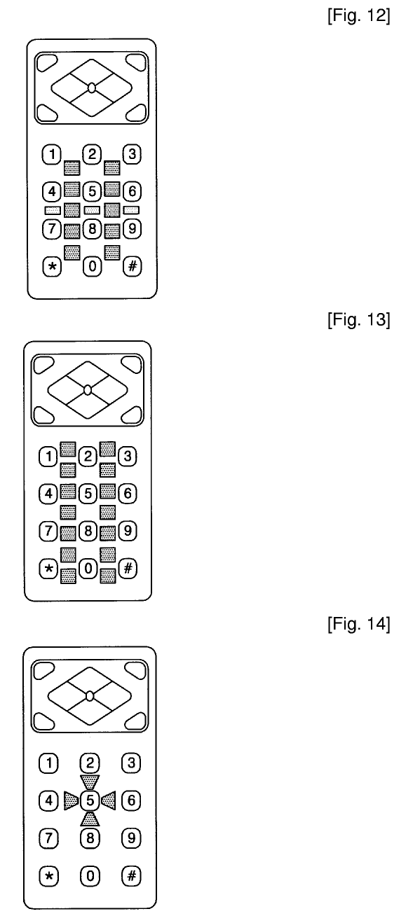

In addition, as shown in FIG. 11 to FIG. 15, an input device in accordance with the present invention includes a plurality of key buttons and contact sensors to provide the same function and effect as the input device shown in FIGS. 3,9 and 10.

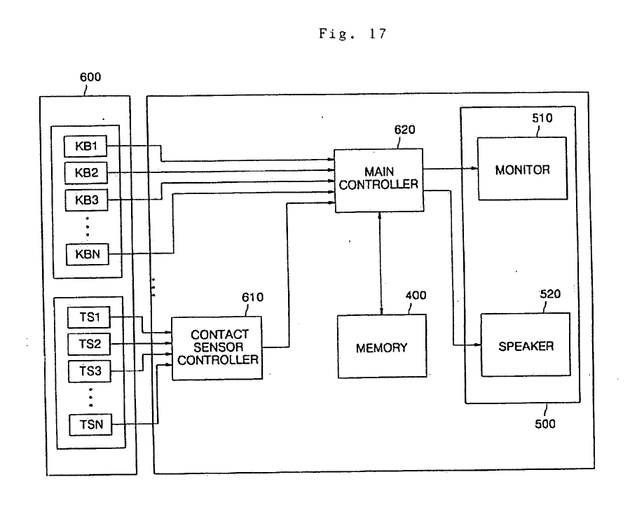

Referring to FIG. 17 to FIG. 15, although the plurality of key buttons are disposed in a matrix similar to the conventional art, the plurality of contact sensors may be disposed on remaining regions, except the regions where the plurality of key buttons are disposed, or on surfaces of the plurality of key buttons in various arrays.

In FIG. 11 to FIG. 15, the regions where the contact sensors are disposed are illustrated as dotted regions.

In FIG. 11, the plurality of contact sensors are disposed in a matrix on the remaining regions except the regions where the plurality of key buttons are disposed, and in FIG. 12, the plurality of contact sensors are disposed in a cross on the remaining regions. In FIG. 13, the plurality of contact sensors are disposed in a line on the remaining regions, in FIG. 14 the plurality of contact sensors are disposed in a circle on the remaining regions, and in FIG. 15, the plurality of contact sensors are disposed on the surfaces of the key buttons.

As described above, an input device in accordance with the present invention includes a plurality of contact sensors disposed on key pad regions or surfaces of key buttons so that the input device can have a plurality of contact sensors as well as the plurality of key buttons, without increasing the size of the input device.

That is, it is possible to detect various input operations to receive various kinds of information, without increasing the kind and size of the input device.

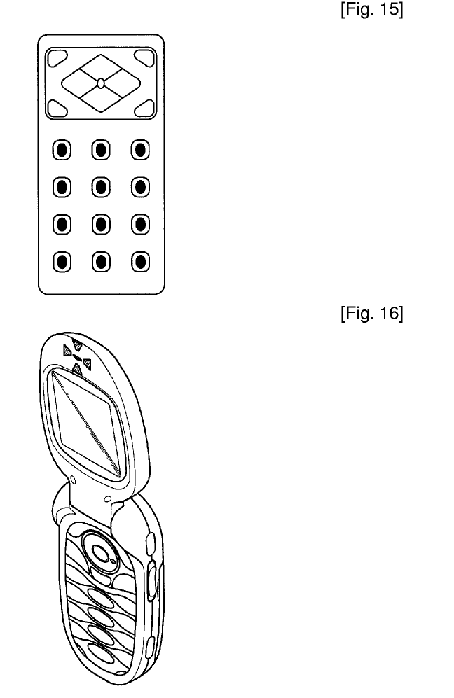

While FIG. 11 to FIG. 15 illustrate the plurality of contact sensors disposed on the keypad, the contact pads may be disposed a region (for example, a peripheral region of a speaker) other than the keypad, as shown in FIG. 16, depending on product characteristics of the content providing device, according to the same manner as FIG. 11 to FIG. 15.

FIG. 17 is a block diagram of a content providing device having the input device of FIG. 11 to FIG. 15 in accordance with an exemplary embodiment of the present invention.

Referring to FIG. 17, the input device includes a user input unit 600, a contact sensor controller 610, a main controller 620, a memory 400, and a data output unit 500 having a monitor 510 and a speaker 520, thereby displaying contents in the scroll mode shown in FIG. 9, or the cursor moving mode shown in FIG. 10, similar to the content driving device shown in FIG. 8.

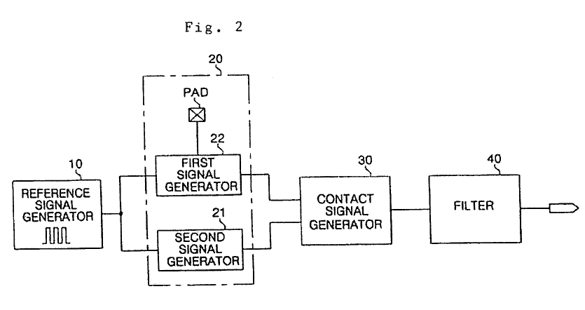

The user input unit 600 includes a plurality of key buttons KB1˜KBn and a plurality of contact sensors TS1˜TSn disposed as shown in FIG. 11 to FIG. 15. When each of the key buttons KB1˜KBn is pushed by a user, the user input unit 600 detects the pushed key button to generate button information, and transmits the button information to the main controller 620. When each of the contact sensors TS1˜TSn is contacted by a user, the user input device 600 detects the contacted sensor to generate a contact signal, and transmits the contact signal to the contact sensor controller 610. At this time, the contact sensor is implemented as the contact sensor shown in FIG. 2.

The contact sensor controller 610 sets and stores each position value and contact position of the plurality of contact sensors TS1˜TSn, or a scroll direction and a cursor moving position corresponding to a moving direction of the contact position, analyzes a plurality of contact signals transmitted from the plurality of contact sensors TS1˜TSn, and obtains a current contact position or a moving direction of the contact position. In addition, when a display mode of the main controller 620 is a scroll mode, the contact sensor controller 610 generates scroll information having the obtained contact position or information of a scroll direction corresponding to the contact position to output the scroll information to the main controller 620, and when a cursor moving mode, the contact sensor controller 610 generates cursor moving information having information about a cursor moving position and then outputs the cursor moving information to the main controller 620.

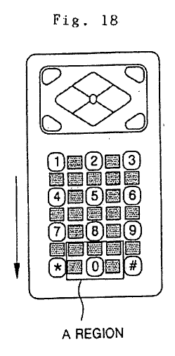

For example, when a user continuously contacts the plurality of contact sensors in the direction of arrow shown in FIG. 18 during the scroll mode, the contact sensor controller 610 detects the contact using a plurality of contact signals, and generates scroll information for scrolling a screen in the direction of an arrow. On the other hand, when the user contacts the plurality of contact sensors disposed in an A region in FIG. 18 during the cursor moving mode, the contact sensor controller 610 detects the contact using a plurality of contact signals, and generates cursor moving information which enables a cursor displayed on a screen to move to a specific position corresponding to the A region.

In addition, the contact sensor controller 610 further includes a data selection condition for directly selecting data displayed on a specific position of the screen. When a plurality of contact signals for satisfying the data selection condition are transmitted, the contact sensor controller 610 generates data selection information for selecting data displayed on a specific position of the screen.

For example, under the condition that the same region (for example, the A region in FIG. 18) contacts twice, when a user contacts the A region twice, the contact sensor controller 610 detects the contact using a plurality of contact signals, and generates data selection information for selecting data displayed on a specific position of the screen corresponding to the A region.

In addition, the contact sensor controller 610 can reset each position value, contact position or scroll direction corresponding to a moving direction of the contact position, cursor moving position, and data selection condition of the plurality of contact sensors TS1˜TSn, according to a user's need.

The main controller 620 controls the entire operation of the content providing device, and provides content in response to a user's request. In particular, the main controller 620 determines a current display mode to inform the determined display mode to the contact sensor controller 610 during the display of the content information. Then, in the case of a scroll mode, the main controller 620 receives scroll information from the contact sensor controller 610 to perform a scroll operation. In the case of a cursor moving mode, the main controller 620 receives cursor moving information from the contact sensor controller 610 to perform a cursor moving operation. In addition, when data selection information is provided from the contact sensor controller 610, regardless of the display mode, the main controller 620 performs a data selection operation in response to the data selection information to select data displayed on a specific position of a screen.

The memory 400 stores data for providing various programs, menus, and contents that can control and perform the entire operation of the content providing device. The monitor 510 of the data output unit 500 converts data transmitted from the main controller 620 into characters and figures recognizable by a user, and displays them on the screen, under the control of the main controller 620. The speaker 520 of the data output unit 500 converts the data transmitted from the main controller 620 into sounds recognizable by a user, and outputs the sounds.

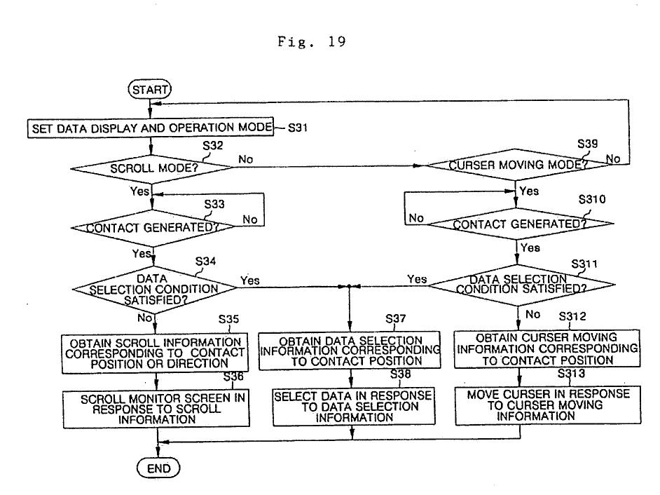

The operation of a content providing device in accordance with the present invention will now be described with reference to FIG. 19.

First, when a user selects data to be displayed, a main controller 620 displays the data, and simultaneously sets a display mode of a content providing device depending on a display type of the data (S31).

When the display mode of the content providing device is set as a scroll mode by step S31 (S32), the main controller 620 informs to the contact sensor controller 610 that the display mode of the content providing device is the scroll mode, and the contact sensor controller 610 monitors a user input unit 600 to detect whether contact by a user is generated (S33).

In step S33, when the user input unit 600 generates a plurality of contact signals by contact of a user, the contact sensor controller 610 determines whether the plurality of contact signals satisfy data selection condition (S34).

As a result of the determination, when the data selection condition is not satisfied, the contact sensor controller 610 analyzes the plurality of contact signals to determine a contact position and a contact position moving direction of the user, and obtains a scroll direction corresponding to the contact position and the contact position moving direction of the user, thereby generating scroll information (S35).

Then, the main controller 620 scrolls a screen in response to the scroll information generated during step S35 (S36).

On the other hand, as a result of the determination of step S34, when the data selection condition is satisfied, the contact sensor controller 610 analyzes the plurality of contact signals to determine the contact position of the user, and generate data selection information corresponding to the contact position (S37).

Then, the main controller 620 selects data displayed on a specific position of a screen corresponding to the contact position (S38), in response to the data selection information generated by step S37.

On the other hand, when the display mode of the content providing device is set as the cursor moving mode by step S31 (S39), the main controller 620 informs to the contact sensor controller 610 that the display mode of the content providing device is the cursor moving mode, and the contact sensor controller 610 monitors the user input unit 600 to detect whether contact by a user is generated (S310).

In step S310, when a plurality of contact signals are generated by contact of the user, the contact sensor controller 610 determines whether the plurality of contact signals satisfy data selection condition (S311), and performs step S37 when the data selection condition is satisfied.

On the other hand, as a result of the determination, when the data selection condition is not satisfied, the contact sensor controller 610 analyzes the plurality of contact signals to determine a contact position of the user, and obtains a cursor moving position corresponding to the contact position of the user, thereby generating cursor moving information (S312).

Then, the main controller 620 moves a cursor to a certain position of a screen corresponding to the contact position of the user (S313), in response to the cursor moving information generated by step S312.

Here, one example of the data selection condition is to use a button. In FIG. 9, when one menu bar is selected, the button usually marked as “OK” or “ENTER” is used to select the menu bar.

As described above, the content providing device of FIG. 11 to FIG. 15 enables the plurality of contact sensors TS1˜TSn and the contact sensor controller 610 to generate scroll information or cursor moving information according to an operation mode, thereby performing a scroll operation or a cursor moving operation in response to the scroll information or the cursor moving information.

While the content providing device of the exemplary embodiment can receive the scroll information and the cursor moving information from the input device to perform both of the scroll operation and the cursor moving operation, if necessary, the input device may provide only one of the scroll information and the cursor moving information, and the content providing device may perform only one of the scroll operation and the cursor moving operation in response to the provided information.

It is natural that contact sensors in FIGS. 11˜19 can be at least partially replaced with pressure sensors. And, loops of S33 and S310 in FIG. 19 with no contact generation can be terminated after a pre-determined time.

While this invention has been described with reference to exemplary embodiments thereof, it will be clear to those of ordinary skill in the art that various modifications can be made to the described embodiments within the spirit and the scope of the invention set forth in the appended claims.

1. An input device for a content providing device comprising:
a pressure sensor having first pressure pads varying impedance according to contact strength, and periodically generating and outputting first pressure data having values corresponding to impedance of each of the first pressure pads;
a button information generator for generating and outputting button information corresponding to the first pressure pad having the largest pressure data, when receiving the first pressure data;
a pointing information generator for obtaining a position value of the first pressure pad having the largest pressure data when receiving the first pressure data, comparing the position value with the previously obtained position value to calculate a movement value of a contact position, and generating and outputting pointing information having the calculated movement value; and
an operation selection unit for transmitting the first pressure data to the button information generator when the first pressure data transmitted from the pressure sensor is different from the previously obtained data and has a value larger than a button input value, and transmitting the first pressure data to the pointing information generator when the first pressure data transmitted from the pressure sensor is different from the previously obtained data and has value smaller than a pointing input value.

2. The input device for a content providing device according to claim 1, wherein the pointing information generator generates the pointing information only when the first pressure data is continuously received within a movement detection time.

3. The input device for a content providing device according to claim 1, wherein the pressure sensor comprises:
the first pressure pads disposed on a keypad; and
a plurality of first pressure data generators respectively corresponding to the first pressure pads, and generating first pressure data having a value corresponding to the impedance of each of the first pressure pads.

4. The input device for a content providing device according to claim 3, wherein the pointing information generator sets a movement correction value on the basis of a relationship between the first pressure pads disposed on both ends of the keypad, corrects the calculated movement value using the movement correction value when the calculated movement value is larger than a movement limit value, and generates the pointing information having the corrected movement value.

5. The input device for a content providing device according to claim 1, wherein the pressure sensor further comprises second pressure pads varying impedance according to contact strength, and periodically generates second pressure data having a value corresponding to impedance of each of the second pressure pads and outputs the second pressure data.

6. The input device for a content providing device according to claim 3, wherein the pressure sensor further comprises:
the second pressure pads disposed on the keypad; and
a plurality of second pressure data generators respectively corresponding to the second pressure pads, and generating second pressure data having a value corresponding to the impedance of each of the second pressure pads.

7. The input device for a content providing device according to claim 5, further comprising a setting information generator that obtains the second pressure pad for generating different second pressure data when second pressure data having a different value from the previous pressure data is received from the pressure sensor, and generates and outputs setting information corresponding to the obtained second pressure pad and a pressure data value of the obtained second pressure pad.

8. The input device for a content providing device according to claim 7, wherein the operation selection unit further comprises functions of setting a predetermined number of the first pressure pads as combined-use pads, and transmitting first input data of the combined-use pads to the setting information generator when at least one of the first input data of the combined-use pads is larger than a pointing input value and smaller than a button input value, and
the setting information generator further comprises functions of obtaining the combined-use pad generating a different value from the previous value when the first input data of the combined-use pads are received from the operation selection unit, and generating and outputting setting information corresponding to the combined-use pad and a pressure data value of the obtained combined-use pad.

9. A content providing device comprising:
a user input unit having first pressure pads varying impedance according to contact strength, and generating button information or pointing information according to user's contact strength with respect to the first pressure pads; and
a controller for performing, when the button information is received, a data selection operation in response to the button information, determining a content display mode when the pointing information is received, scrolling a screen in response to the pointing information when the display mode is a scroll mode, and moving a cursor displayed on the screen in response to the pointing information when a cursor moving mode.

10. The content providing device according to claim 9, wherein the user input unit comprises:
a pressure sensor having the first pressure pads, and periodically generating and outputting first pressure data having a value corresponding to impedance of each of the first pressure pads;
a button information generator for generating and outputting button information corresponding to the first pressure pad having the largest pressure data when receiving the first pressure data;
a pointing information generator for obtaining a position value of the first pressure pad having the largest pressure data when receiving the first pressure data, comparing the position value with the previously obtained position value to calculate a movement value of a contact position, and generating and outputting pointing information having the calculated movement value; and
an operation selection unit for transmitting the first pressure data to the button information generator when the first pressure data transmitted from the pressure sensor is different from the previously obtained data and has a value larger than a button input value, and transmitting the first pressure data to the pointing information generator when the first pressure data transmitted from the pressure sensor is different from the previously obtained data and has value smaller than a pointing input value.

11. The content providing device according to claim 10, wherein the pointing information generator generates the pointing information only when the first pressure data is continuously received within a movement detection time.

12. The content providing device according to claim 10, wherein the pressure sensor comprises:
the first pressure pads disposed on a keypad; and
a plurality of pressure data generators corresponding to the first pressure pads, and generating first pressure data having a value corresponding to the impedance of each of the first pressure pads.

13. The content providing device according to claim 12, wherein the pointing information generator sets a movement correction value on the basis of a relationship between the first pressure pads disposed on both ends of the user input unit, corrects the calculated movement value using the movement correction value when the calculated movement value is larger than a movement limit value, and generates the pointing information having the corrected movement value.

14. The content providing device according to claim 10, wherein the pressure sensor further comprises second pressure pads varying impedance according to contact strength, and periodically generates second pressure data having a value corresponding to the impedance of each of the second pressure pads and outputs the second pressure data.

15. The content providing device according to claim 12, wherein the pressure sensor further comprises:
the second pressure pads disposed on the user input unit; and
a plurality of second pressure data generators respectively corresponding to the second pressure pads, and generating second pressure data having a value corresponding to the impedance of each of the second pressure pads.

16. The content providing device according to claim 14, wherein an input device for the content providing device further comprises a setting information generator which obtains the second pressure pad for generating different second pressure data when second pressure data having a different value from the previous pressure data is received from the pressure sensor, and generates and outputs setting information corresponding to the obtained second pressure pad and a pressure data value of the obtained second pressure pad.

17. The content providing device according to claim 16, wherein the operation selection unit further comprises functions of setting a predetermined number of the first pressure pads as combined-use pads, and transmitting first input data of the combined-use pads to the setting information generator when at least one of the first input data of the combined-use pads is larger than a pointing input value and smaller than a button input value, and
the setting information generator further comprises functions of obtaining the combined-use pad generating a different value from the previous value when first pressure data of the combined-use pads is received from the operation selection unit, and generating and outputting setting information corresponding to the combined-use pad and a pressure data value of the obtained combined-use pad.

18. A content providing terminal comprising:
a user input unit having a plurality of key buttons and a plurality of contact sensors, and generating a plurality of button information and a plurality of contact signals;
a contact sensor controller for recognizing a contact position or a contact position moving direction in response to the plurality of contact signals, generating scroll information corresponding to the contact position or the contact position moving direction in a scroll mode, and generating cursor moving information corresponding to the contact position in a cursor moving mode; and
a main controller for setting a display mode according to a display type of content, scrolling a screen in response to the scroll information generated by the contact sensor controller in the scroll mode, and moving a cursor displayed on the screen in response to the cursor moving information generated by the contact sensor controller in the cursor moving mode.

19. The content providing terminal according to claim 18, wherein the contact sensor controller further comprises a data selection condition, and a function of generating data selection information in response to the plurality of contact signals, when the plurality of contact signals satisfying the data selection condition are received.

20. The content providing terminal according to claim 19 wherein the main controller further comprises a function of selecting data displayed on a certain position of the screen, in response to the data selection information.

21. The content providing terminal according to claim 18, wherein the user input unit comprises the plurality of contact sensors disposed in a matrix on remaining regions except the region on which the plurality of key buttons are disposed.

22. The content providing terminal according to claim 18, wherein the user input unit comprises the plurality of contact sensors disposed in a cross on remaining regions except the region on which the plurality of key buttons are disposed.

23. The content providing terminal according to claim 18, wherein the user input unit comprises the plurality of contact sensors disposed in a circle on remaining regions except the region on which the plurality of key buttons are disposed.

24. The content providing terminal according to claim 18, wherein the user input unit comprises the plurality of contact sensors disposed on the plurality of key buttons.

25. The content providing terminal according to claim 18, wherein the user input unit comprises the plurality of contact sensors disposed in a line on remaining regions except the region on which the plurality of key buttons are disposed.

26. The content providing terminal according to claim 18, further comprising a speaker for outputting sound,
and the plurality of contact sensors are disposed around the speaker.

27. The content providing terminal according to claim 18, wherein the user input unit further comprises one or more pressure pads varying impedance according to contact strength to generate one or more either scroll signals or pointing signals corresponding to impedance of each of the pressure pads.

28. A method of operating an input device for a content providing device having first and second pressure pads disposed on a keypad and varying impedance according to contact strength of a user, the method comprising:
a pressure data generating step of periodically generating a plurality of first pressure data having values corresponding to impedance of each of the first pressure pads;
a determination step of determining whether at least one first pressure data has a value larger than a button input value when a newly obtained first pressure data is different from the previously obtained first pressure data;
a button information generating step of obtaining the first pressure pad having the largest first pressure data, and generating and outputting button information corresponding to the obtained first pressure pad, when the at least one first pressure data has a value larger than the button input value as a result of the determination; and
a pointing information step of obtaining a position value of the first pressure pad having the largest first pressure data, comparing the position value with the previously obtained position value to calculate a movement value of a contact position, and generating and outputting pointing information having the calculated movement value, when all of the first pressure data have values not more than the pointing input value as a result of the determination.

29. The method according to claim 28, wherein the pointing information step comprises:
a position value obtaining step of obtaining a position value of the first pressure pad having the largest first pressure data, when all of the first pressure data have values not more than a pointing input value as a result of the determination;
a time determination step of determining whether the new position value is obtained within a movement detection time;
a movement value calculation step of calculating a movement value of a contact position by comparing the new position value with the previous position value, when the new position value is obtained within the movement detection time; and
a pointing information generating step of generating the pointing information having the calculated movement value.

30. The method according to claim 29, wherein the pointing information generating step further comprises:
a movement correction value setting step of setting a movement correction value on the basis of a relationship between the first pressure pads disposed on both ends of the user input unit; and
a movement value correction step of correcting the calculated movement value using the movement correction value, when the calculated movement value is larger than a movement limit value.

31. The method according to claim 28, further comprising:
a pressure data generating step of periodically generating second pressure data having a value corresponding to impedance of each of the second pressure pads; and
a step of generating setting information corresponding to second pressure data having a different value from the previous value and the second pressure pad having the pressure data, when the newly obtained second pressure data is different from the previously obtained second pressure data.

32. The input device for a content providing device according to claim 5, wherein the pressure sensor further comprises:
the second pressure pads disposed on the keypad; and
a plurality of second pressure data generators respectively corresponding to the second pressure pads, and generating second pressure data having a value corresponding to the impedance of each of the second pressure pads.

33. The content providing device according to claim 14, wherein the pressure sensor further comprises:
the second pressure pads disposed on the user input unit; and
a plurality of second pressure data generators respectively corresponding to the second pressure pads, and generating second pressure data having a value corresponding to the impedance of each of the second pressure pads.
